(19) United States
(12) Patent Application Publication
(10) Pub. No.: US 2007/0236758 A1
(43) Pub. Date: Oct. 11, 2007

(54) Image processing apparatus and image processing method

(75) Inventor: Norimasa Ariga, Izunokuni-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignees: Kabushiki Kaisha Toshiba, Minato-ku (JP); Toshiba Tec Kabushiki Kaisha, Shinagawa-ku (JP)

(21) Appl. No.: 11/400,677

(22) Filed: Apr. 7, 2006

(51) Int. Cl. G03F 3/08

(52) U.S. Cl. 358/518; 358/1.9

(57) ABSTRACT

In an image processing apparatus 1, a LDLUT generation unit generates LDLUT data, and the obtained input value is stored as normalized data similarly to pixel data of an input image. A 3DLUT generation unit generates first 3DLUT data. Based on the LDLUT data and the first 3DLUT data and from the input image, a first color conversion unit uses various table interpolation methods and calculates CMYK values as color material amounts of an output device (output image).

### BACKGROUND OF THE INVENTION

1. Field of the Invention

The present invention relates to an image processing apparatus and an image processing method in which for example, an RGB input image inputted from a host computer is conversion processed into a CMYK output image so that it is outputted by a printer.

2. Description of the Related Art

Conventionally, in an image processing apparatus in a color printer, two color conversion paths are often provided. One (path 1) of the two color conversion paths is a path passing through normal color conversion parameters, in which an inputted color signal (for example, RGB) is converted into a color signal (CMYK) corresponding to the color material of the printer. The other path (path 2) is a path which is used in a case where an inputted color signal is achromatic, and is a path in which conversion is performed so as to reproduce the inputted color by only the black (K) color material of the printer.

The path 1 is used in the case where the inputted color signal represents the chromatic color. The path 2 is used only when the inputted color signal represents the achromatic color.

For example, in the case where a character with 50% achromatic color (R=G=B=50%) is inputted, the result of the color conversion by the path 1 becomes C=20%, M=10%, Y=10% and K=30%, and these are printed by output means. However, the output means normally has some output positional deviation as a mechanical unstable element, and the respective data of CMYK are not necessarily outputted to the same positions. That is, there is a case where the output result is such that the positions of CMYK respectively deviate. At this time, a color blur occurs in the contour part of the outputted character, and deterioration in picture quality occurs.

Besides, for example, in the case where a character with 50% achromatic color is inputted similarly, the result of the color conversion by the path 2 becomes C=0%, M=0%, Y=0% and K=45%. Since the color conversion result by the path 2 is only the black (K) color material, even if the positional deviation occurs in the output means, the blur of the contour part does not occur and the deterioration in picture quality does not occur.

As stated above, in the path 2, in the case where an inputted color signal represents an almost achromatic color, the color conversion becomes possible without degrading the picture quality. Such a processing is called a pure gray processing. Incidentally, the path 2 is effective only when the input is the achromatic color, and accordingly, judgment/branch means is provided, and the path 1 is used in the case where the inputted color signal represents the chromatic color, and the path 2 is used in the case of the achromatic color.

However, the number of pixels in A4 size and 300 dpi reaches approximately 8 million pixels. For example, when the pure gray processing is performed on such an image, the judgment processing is conventionally performed 8 million times. In general, when a judgment processing occurs, since a process is changed according to the result of the judgment, for example, the pipeline structure of look-ahead caching in the inside of a CPU is disturbed, and the processing speed is lowered. When the number of judgment processings is small, there does not arise a problem, however, when the judgment processing is performed as many as 8 million times, a serious problem in performance arises.

### BRIEF SUMMARY OF THE INVENTION

The object of an aspect of the present invention is to provide an image processing apparatus and an image processing method in which a pure gray processing can be performed at high speed in color conversion.

According to an aspect of the present invention, there is provided an image processing apparatus including first color conversion data in which a relationship between a color in a color space corresponding to an input image and a color corresponding thereto in a device-independent color space is recorded, second color conversion data in which a relationship between a color material amount of an output equipment and a color corresponding thereto in the device-independent color space is recorded, pure gray data in which a value of a black color amount corresponding to lightness is described, achromatic color on-axis lattice point calculation means for calculating achromatic color on-axis lattice point data from the first color conversion data, one-dimensional look-up table generation means for generating one-dimensional look-up table data from the achromatic color on-axis lattice point data calculated by the achromatic color on-axis lattice point calculation means, three-dimensional look-up table generation means for generating first three-dimensional look-up table data from the first color conversion data, the second color conversion data, and the pure gray data, and first color conversion means for converting the input image into the color material amount of the output device from the one-dimensional look-up table data generated by the one-dimensional look-up table generation means and the first three-dimensional look-up table data generated by the three-dimensional look-up table generation means.

According to another aspect of the present invention, there is provided an image processing method for performing an image processing having first color conversion data in which a relationship between a color in a color space corresponding to an input image and a color corresponding thereto in a device-independent color space is recorded, second color conversion data in which a relationship between a color material amount of an output equipment and a color corresponding thereto in the device-independent color space is recorded, and pure gray data in which a value of a black amount corresponding to lightness is described, the method comprising: calculating achromatic color on-axis lattice point data from the first color conversion data; generating one-dimensional look-up table data from the calculated achromatic color on-axis lattice point data; generating first three-dimensional look-up table data from the first color conversion data, the second color conversion data and the pure gray data; and converting the input image into the color material amount of the output device from the generated one-dimensional look-up table data and the generated first three-dimensional look-up table data.

Additional objects and advantages of an aspect of the invention will be set forth in the description which follows, and in part will be obvious from the description, or may be learned by practice of the invention. The objects and advantages of an aspect of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate preferred embodiments of the invention, and together with the general description given above and the detailed description of the embodiments given below, serve to explain the principles of an aspect of the invention.

FIG. 1 is a view showing a schematic structure of an image processing apparatus of the invention;

FIG. 2 is a block diagram showing a schematic structure of an image processing apparatus 1 of the invention;

FIG. 3 is a view showing a schematic structure of 3DLUT generation means;

FIG. 4 is a view showing a schematic structure of second color conversion means; and

FIG. 5 is a view showing a structure of a conventional image processing apparatus.

### DETAILED DESCRIPTION OF THE INVENTION

Hereinafter, an embodiment of the invention will be described with reference to the drawings.

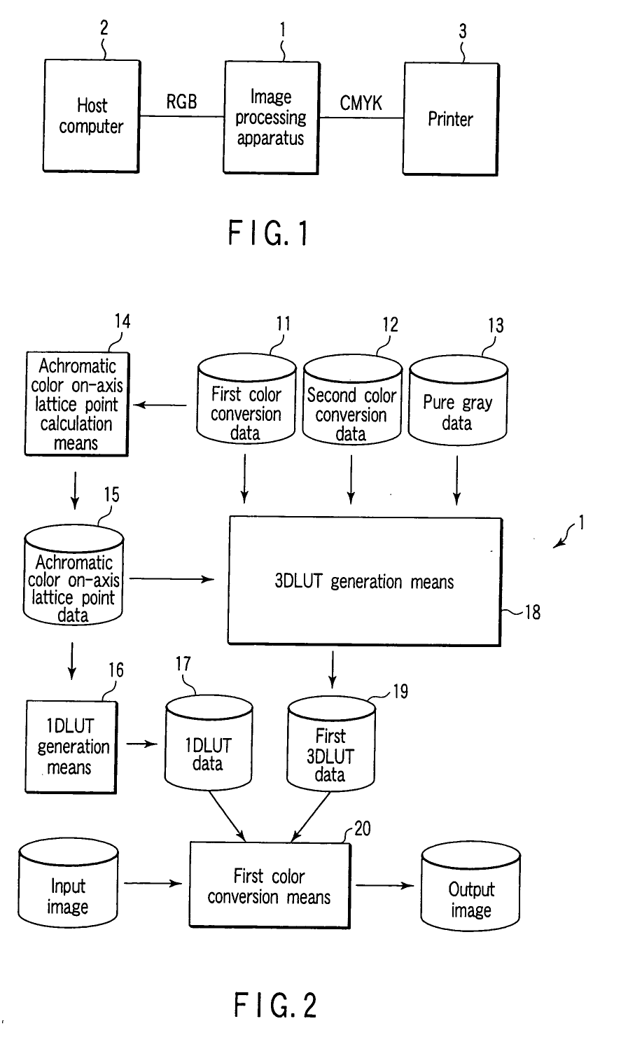

FIG. 1 shows a print system of an image processing apparatus of the invention. A host computer 2 sends a desired print output as an image in an arbitrary color space (for example, RGB) to an image processing apparatus 1. The image processing apparatus 1 performs an image processing to convert the image received from the host computer 2 into color material amounts (for example, CMYK) to output by a printer 3. The printer 3 performs printing based on the color material amounts.

FIG. 2 shows a schematic structure of the image processing apparatus 1 of the invention. The image processing apparatus 1 includes at least first color conversion data 11, second color conversion data 12, pure gray data 13, achromatic color on-axis lattice point calculation means 14, achromatic color on-axis lattice point data 15, LDLUT generation means 16 for generating a one-dimensional look-up table, LDLUT data 17 as one-dimensional look-up table data, 3DLUT generation means 18 for generating a three-dimensional look-up table, first 3DLUT data 19 as three-dimensional look-up table data, and first color conversion means 20.

In the first color conversion data 11, there is recorded a relationship between a color in a color space corresponding to an input image and a color corresponding thereto in a device-independent color space. It is, for example, a relation table between RGB values and CIELAB values, and there is a case where the relationship is determined by measurement, or there is also a case where it is determined as a standard. It is unnecessary that this table is previously determined, and there can be a case where it is transmitted together with an input image.

In the second color conversion data 12, there is recorded a relationship between a color material amount for an output equipment and a color corresponding thereto in the device-independent color space. It is, for example, a relation table between CMYK amounts printed by the printer 3 shown in FIG. 1 and the CIELAB values, and the relationship is often determined by measurement, however, there is also a case where it is determined as a standard. This table is a previously determined correspondingly to the output device, and is required to be successively changed when the output device is changed.

In the pure gray data 13, values of K amounts (black color amounts) corresponding to lightness are described. For example, it is a table in which there are described values of the lightness corresponding to the respective K amounts at the time when CMY are respectively 0 in the combination of the CMYK amounts to be printed by the printer 3 shown in FIG. 1.

The achromatic color on-axis lattice point calculation means 14 is means for obtaining a desired CIELAB value from the first color conversion data 11. For example, when an input image is an image of the RGB color space, the first color conversion data 11 is a table including RGB values—CIELAB values. Following relational expressions are deduced from this table by using an error least square approximation method.
R=A11*Lˆ2+A12*aˆ2+A13*bˆ2+A14*L*a+A15*L*b+A16*a*b+A17*L+A18*a+A19*b+A10
G=A21*Lˆ2+A22*aˆ2+A23*bˆ2+A24*L*a+A25*L*b+A26*a*b+A27*L+A28*a+A29*b+A20
B=A31*Lˆ2+A32*aˆ2+A33*bˆ2+A34*L*a+A35*L*b+A36*a*b+A37*L+A38*a+A39*b+A30

Desired CIELAB values are substituted for the expressions. Since the desired CIELAB values are points on the achromatic color axis, the values of a* and b* are “0”, and L* becomes arbitrary values at equal intervals. For example, in the case where the first 3DLUT data 19 of 11 grid points is required, 11 points incremented by 100/(11−1) from “0” to “100” are inputted, and the RGB values at the 11 points are calculated.

The achromatic color on-axis lattice point data 15 is data obtained from the achromatic color on-axis lattice point calculation means 14, and RGB values corresponding to values of L* are stored.

The 1DLUT generation means 16 is means for generating 1DLUT from the achromatic color on-axis lattice point data 15. Specifically, the achromatic color on-axis lattice point data 15 is divided for each channel, and values outputted when R, G and B for each channel are inputted are generated to be spaced at equal intervals. For example, consideration is given to a case where the achromatic color on-axis lattice point data 15 has the following structure.

| L | R | G | B |
|---|---|---|---|
| 0 | 0 | 0 | 0 |
| 10 | 22 | 27 | 25 |
| 20 | 45 | 55 | 52 |
| 30 | 67 | 75 | 80 |
| 40 | 90 | 99 | 98 |
| 50 | 120 | 130 | 127 |
| 60 | 151 | 165 | 158 |
| 70 | 179 | 199 | 189 |
| 80 | 213 | 225 | 220 |
| 90 | 240 | 243 | 242 |
| 100 | 255 | 255 | 255 |

At this time, the lightness L of the achromatic color on-axis lattice point data 15 and data for each channel are extracted and calculation is performed. Specifically, input values are calculated in which eleven equally spaced R values are obtained from the combination of the R values with respect to the lightness L by a spline interpolation calculation or the like. Similar calculation is performed also with respect to G and B, and the LDLUT is generated.

The LDLUT data 17 is LDLUT data generated by the LDLUT generation means 16, and the input values obtained by the LDLUT generation means 16 are stored as normalized data similarly to the pixel data of the input image.

The 3DLUT generation means 18 is means for generating first 3DLUT data.

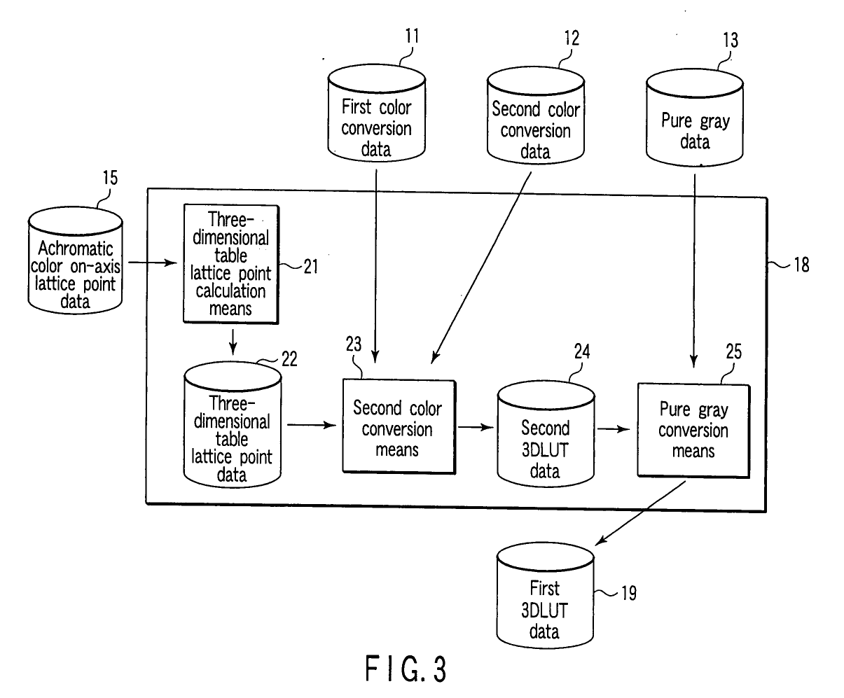

FIG. 3 shows a schematic structure of the 3DLUT generation means 18. That is, the 3DLUT generation means 18 includes three-dimensional table lattice point calculation means 21, three-dimensional table lattice point data 22, second color conversion means 23, second 3DLUT data 24, and pure gray conversion means 25.

The three-dimensional table lattice point calculation means 21 generates, based on the achromatic color on-axis lattice point data 15, the three-dimensional table lattice point data 22 which becomes the origin of lattice points of the first 3DLUT data 19. For example, consideration is given to a case where the achromatic color on-axis lattice point data has the following structure.

| L | R | G | B |
|---|---|---|---|
| 0 | 0 | 0 | 0 |
| 10 | 22 | 27 | 25 |
| 20 | 45 | 55 | 52 |
| 30 | 67 | 75 | 80 |
| 40 | 90 | 99 | 98 |
| 50 | 120 | 130 | 127 |
| 60 | 151 | 165 | 158 |
| 70 | 179 | 199 | 189 |
| 80 | 213 | 225 | 220 |
| 90 | 240 | 243 | 242 |
| 100 | 255 | 255 | 255 |

The structure is such that R has 11 points, G has 11 points, and B has 11 points, and data of a combination of the respective points is generated. Specifically, the three-dimensional table lattice point data 22 become table data of 11*11*11=1331 points, and are stored in order indicated below.

| R | G | B |
|---|---|---|
| 0 | 0 | 0 |
| 0 | 0 | 25 |
| 0 | 0 | 52 |
| 0 | 0 | 80 |
| : | : | : |
| : | : | : |
| 0 | 0 | 255 |
| 0 | 27 | 0 |
| 0 | 27 | 25 |
| 0 | 27 | 52 |
| : | : | : |
| : | : | : |
| 0 | 255 | 255 |
| 22 | 0 | 0 |
| 22 | 0 | 25 |
| 22 | 0 | 52 |
| : | : | : |
| 255 | 255 | 255 |

The second color conversion means 23 performs conversion to values of color material amounts in an output device corresponding to the three-dimensional table lattice point data 22 calculated by the three-dimensional table lattice point calculation means 21.

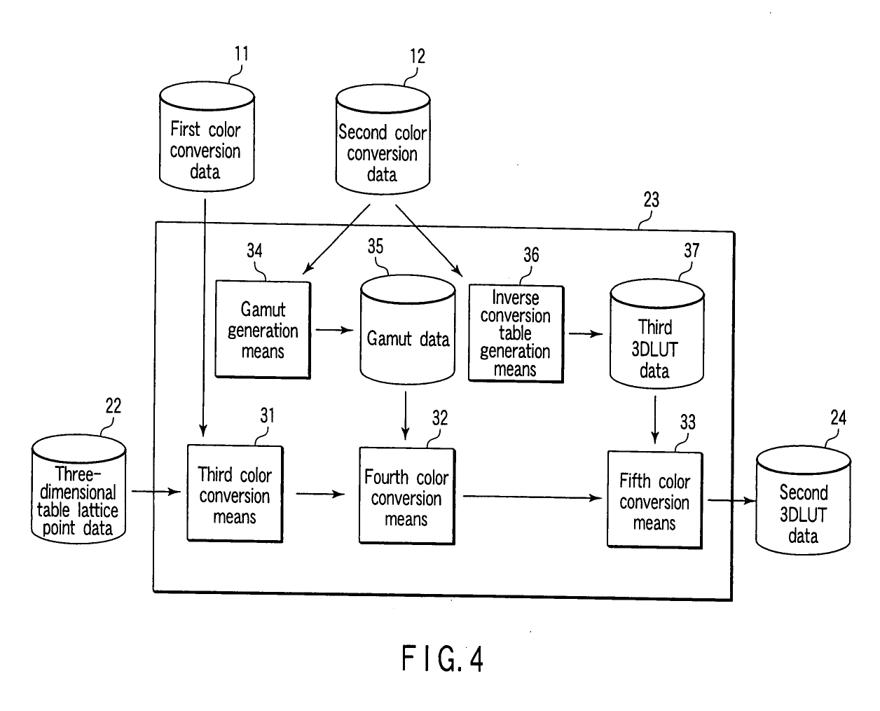

FIG. 4 shows a schematic structure of the second color conversion means 23. That is, the second color conversion means 23 includes third color conversion means 31, fourth color conversion means 32, fifth color conversion means 33, gamut generation means 34, gamut data 35, inverse conversion table generation means 36, and third 3DLUT data 37.

The third color conversion means 31 performs a processing to convert RGB of the three-dimensional table lattice point data 22 into CIELAB. This conversion is performed based on the first color conversion table 11. The color conversion data used at this time is data for matrix calculation or a table for interpolation calculation. The matrix calculation is performed when the color conversion data is the matrix, and the interpolation calculation is performed when it is the table for interpolation calculation, and the color space of the input image is converted.

Hereinafter, computation expressions in the case of the matrix calculation are indicated.
L*=A11*Rˆ2+A12*Gˆ2+A13*Bˆ2+A14*R*G+A15*R*B+A16*G*B+A17*R+A18*G+A19*B+A10
a*=A21*Rˆ2+A22*Gˆ2+A23*Bˆ2+A24*R*G+A25*R*B+A26*G*B+A27*R+A28*G+A29*b+A20
b*=A31*Rˆ2+A32*Gˆ2+A33*Bˆ2+A34*R*G+A35*R*B+A36*G*B+A37*R+A38*G+A39*B+A30

That is, values of from A10 to A39 are delivered as the first color conversion data 11 to the fourth color conversion means 32.

The gamut generation means 34 generates the gamut data 35 based on the second color conversion data 12. In the case where the second color conversion data is CMYK, there are extracted CIELAB values in plural states of K=0, and CIELAB values in states where at each K, any one of C, M and Y is 100% and any one of C, M and Y is 0%.

The fourth color conversion means 32 performs a processing to convert the CIELAB value to a CIELAB value. This conversion is conversion including a gamut mapping, and is a calculation processing to perform the gamut mapping based on the gamut data 35 generated by the gamut generation means 34. When the CIELAB value of the three-dimensional table lattice point data 22 inputted to the fourth color conversion means 32 does not exist in a closed space of the gamut data 35, it is judged to be outside the gamut, and the nearest gamut data 35 is extracted and is outputted as a new CIELAB value.

The inverse conversion table generation means 36 generates, based on the second color conversion data 12, the third 3DLUT data 37 used in the fifth color conversion means 33 as discrete table data which is a set of data of points (grid points) arranged at equal intervals in the device-independent color space. The following relational expressions are deduced from the second color conversion data 12 by using the error least square approximation method.
C=A11*Lˆ2+A12*aˆ2+A13*bˆ2+A14*L*a+A15*L*b+A16*a*b+A17*L+A18*a+A19*b+A10+A1a*Kˆ2+A1b*K*L+A1c*K*a+A1d*K*b+A1e*K
M=A21*Lˆ2+A22*aˆ2+A23*bˆ2+A24*L*a+A25*L*b+A26*a*b+A27*L+A28*a+A29*b+A20+A2a*Kˆ2+A2b*K*L+A2c*K*a+A2d*K*b+A2e*K
Y=A31*Lˆ2+A32*aˆ2+A33*bˆ2+A34*L*a+A35*L*b+A36*a*b+A37*L+A38*a+A39*b+A30+A3a*Kˆ2+A3b*K*L+A3c*K*a+A3d*K*b+A3e*K

The CIELAB values of the respective lattice points and values of K are substituted for the expressions.

Since the value of K correlates with the lightness and the chroma saturation, it is calculated by a following expression.

if L > 50

K = 0;

elseif sqrt(a\hat{ }2 + b\hat{ }2) > 20

K = 0;

else

K = ((50 − Lmin) − L)/(50 − Lmin)*(1 − sqrt(a\hat{ }2 +

b\hat{ }2)/20)
(value of K is from 0 to 100).

The fifth color conversion means 33 performs a processing to convert CIELAB into CMYK and to generate the second 3DLUT 24. This conversion is performed based on the third 3DLUT data 37. The third 3DLUT data 37 is the set of data of the points (grid points) arranged at equal intervals in the device-independent color space, and has the discrete table data structure.

In the processing to convert the CIELAB into the CMYK, with respect to pixels Li, ai and bi of an image to be converted, in the first color space of the table data, eight table data

L0, a0, b0 : C0, M0, Y0, K0
L0, a0, b1 : C1, M1, Y1, K1
L0, a1, b0 : C2, M2, Y2, K2
L0, a1, b1 : C3, M3, Y3, K3
L1, a0, b0 : C4, M4, Y4, K4
L1, a0, b1 : C5, M5, Y5, K5
L1, a1, b0 : C6, M6, Y6, K6
L1, a1, b1 : C7, M7, Y7, K7
(where, L0 < Li < L1, a0 < ai < a1, b0 < bi < b1)

surrounding the pixels are extracted, and according to the number of dimensions of the color space, interpolation calculation is performed by the linear conversion of

$$\begin{matrix}Co = C 0 + \\ ( C 1 - C 0 ) * ( bi - b 0 ) / ( b 1 - b 0 ) + \\ ( C 2 - C 0 ) * ( ai - a 0 ) / ( a 1 - a 0 ) + \\ ( C 4 - C 0 ) * ( Li - L 0 ) / ( L 1 - L 0 ) + \\ ( C 3 - C 2 - C 1 + C 0 ) * ( ai - a 0 ) / ( a 1 - a 0 ) * ( bi - b 0 ) / ( b 1 - b 0 ) + \\ ( C 5 - C 4 - C 1 + C 0 ) * ( Li - L 0 ) / ( L 1 - L 0 ) * ( bi - b 0 ) / ( b 1 - b 0 ) + \\ ( C 6 - C 4 - C 2 + C 0 ) * ( Li - L 0 ) / ( L 1 - L 0 ) * ( ai - a 0 ) / ( a 1 - a 0 ) + \\ ( C 7 - C 6 - C 5 - C 3 + C 1 + C 4 + C 2 - C 0 ) * \\ ( Li - L 0 ) / ( L 1 - L 0 ) * ( ai - a 0 ) / ( a 1 - a 0 ) * ( bi - b 0 ) / ( b 1 - b 0 )\end{matrix}$$

$$\begin{matrix}Mo = M 0 + \\ ( M 1 - M 0 ) * ( bi - b 0 ) / ( b 1 - b 0 ) + \\ ( M 2 - M 0 ) * ( ai - a 0 ) / ( a 1 - a 0 ) + \\ ( M 4 - M 0 ) * ( Li - L 0 ) / ( L 1 - L 0 ) + \\ ( M 3 - M 2 - M 1 + M 0 ) * ( ai - a 0 ) / ( a 1 - a 0 ) * ( bi - b 0 ) / ( b 1 - b 0 ) + \\ ( M 5 - M 4 - M 1 + M 0 ) * ( Li - L 0 ) / ( L 1 - L 0 ) * ( bi - b 0 ) / ( b 1 - b 0 ) + \\ ( M 6 - M 4 - M 2 + M 0 ) * ( Li - L 0 ) / ( L 1 - L 0 ) * ( ai - a 0 ) / ( a 1 - a 0 ) + \\ ( M 7 - M 6 - M 5 - M 3 + M 1 + M 4 + M 2 - M 0 ) * \\ ( Li - L 0 ) / ( L 1 - L 0 ) * ( ai - a 0 ) / ( a 1 - a 0 ) * ( bi - b 0 ) / ( b 1 - b 0 )\end{matrix}$$

$$\begin{matrix}Yo = Y 0 + \\ ( Y 1 - Y 0 ) * ( bi - b 0 ) / ( b 1 - b 0 ) + \\ ( Y 2 - Y 0 ) * ( ai - a 0 ) / ( a 1 - a 0 ) + \\ ( Y 4 - Y 0 ) * ( Li - L 0 ) / ( L 1 - L 0 ) + \\ ( Y 3 - Y 2 - Y 1 + Y 0 ) * ( ai - a 0 ) / ( a 1 - a 0 ) * ( bi - b 0 ) / ( b 1 - b 0 ) + \\ ( Y 5 - Y 4 - Y 1 + Y 0 ) * ( Li - L 0 ) / ( L 1 - L 0 ) * ( bi - b 0 ) / ( b 1 - b 0 ) + \\ ( Y 6 - Y 4 - Y 2 + Y 0 ) * ( Li - L 0 ) / ( L 1 - L 0 ) * ( ai - a 0 ) / ( a 1 - a 0 ) + \\ ( Y 7 - Y 6 - Y 5 - Y 3 + Y 1 + Y 4 + Y 2 - Y 0 ) * \\ ( Li - L 0 ) / ( L 1 - L 0 ) * ( ai - a 0 ) / ( a 1 - a 0 ) * ( bi - b 0 ) / ( b 1 - b 0 )\end{matrix}$$

$$\begin{matrix}Ko = K 0 + \\ ( K 1 - K 0 ) * ( bi - b 0 ) / ( b 1 - b 0 ) + \\ ( K 2 - K 0 ) * ( ai - a 0 ) / ( a 1 - a 0 ) + \\ ( K 4 - K 0 ) * ( Li - L 0 ) / ( L 1 - L 0 ) + \\ ( K 3 - K 2 - K 1 + K 0 ) * ( ai - a 0 ) / ( a 1 - a 0 ) * ( bi - b 0 ) / ( b 1 - b 0 ) + \\ ( K 5 - K 4 - K 1 + K0 ) * ( Li - L 0 ) / ( L 1 - L 0 ) * ( bi - b 0 ) / ( b 1 - b 0 ) + \\ ( K 6 - K 4 - K 2 + K0 ) * ( Li - L 0 ) / ( L 1 - L 0 ) * ( ai - a 0 ) / ( a 1 - a 0 ) + \\ ( K 7 - K 6 - K 5 - K 3 + K 1 + K 4 + K 2 - K 0 ) * \\ ( Li - L 0 ) / ( L 1 - L 0 ) * ( ai - a 0 ) / ( a 1 - a 0 ) * ( bi - b 0 ) / ( b 1 - b 0 )\end{matrix}$$

and as a result, the conversion into the CMYK is performed.

As described above, the three-dimensional table lattice point data 22 is converted into the second 3DLUT data 24 by the second color conversion means 23.

The second 3DLUT data 24 generated by the second color conversion means 23 is constructed such that values of the lattice points on the diagonal line correspond to the achromatic color, and the L* values are spaced at equal intervals. Specifically, the data of 11 points are constructed of 11 points of from L* value of “0” to “100” at intervals of 10 steps.

In the pure gray conversion means 25, based on the pure gray data 13, values on the diagonal line of the lattice points of the second 3DLUT data 24 corresponding to the achromatic color are changed to the respective K amounts at the time when CMY are respectively 0. In this way, the first 3DLUT data 19 is generated.

Based on the LDLUT data 17 and the first 3DLUT data 19, the first color conversion means 20 uses various table interpolation methods on the input image and calculates the CMYK values as the color material amounts of the output device (output image).

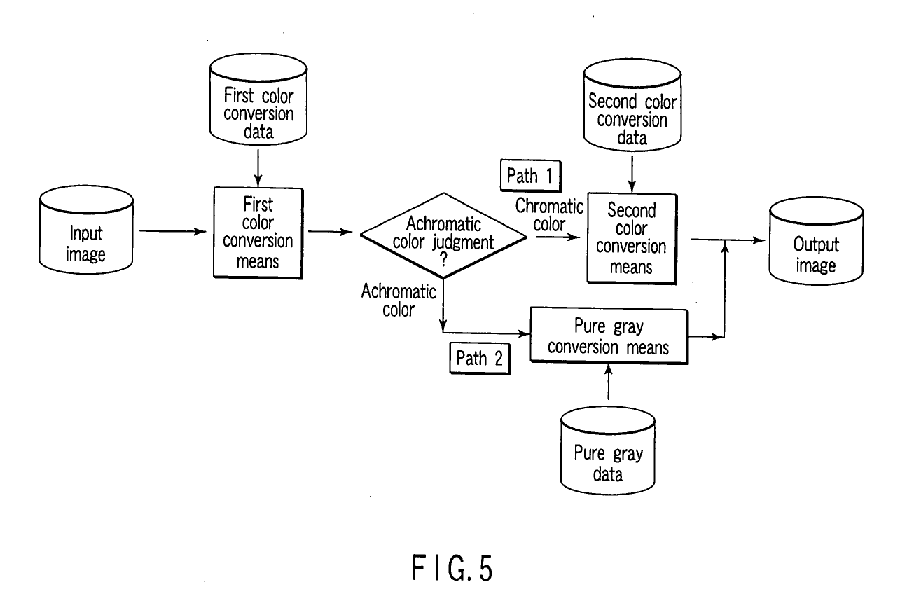

As compared with the embodiment as described above, a conventional image processing apparatus has a structure as shown in FIG. 5, in which judgment/branch means is provided, path 1 is used in the case where an inputted color signal represents a chromatic color, and path 2 is used in the case of an achromatic color. Thus, in the pure gray processing, for example, the number of pixels in A4 size and 300 dpi reaches approximately 8 million pixels, and the judgment processing must be performed as many as 8 million times.

On the other hand, in this embodiment, the improvement in performance is achieved by the following method.

(1) Only one color conversion using 3DLUT is performed.

(2) Pure gray judgment for each pixel is eliminated.

Specifically, as described above, the device colors RGB at L* axis equal division on the achromatic color axis of the input device are calculated from the color characteristic of the RGB input device, the color data of the combination of the respective RGB values is formed, and after they are converted into the colors of the output device, the device colors CMYK of the pure gray are overwritten on the lattice points on the diagonal line, and the RGB-CMYK conversion table is generated. From the device colors RGB at L* axis equal division on the achromatic color axis of the input device from the color characteristic of the RGB input device, the 1DLUT in which the device colors are uniformly arranged is generated.

As described above, according to the embodiment of the invention, the pure gray processing can be performed at higher speed than the conventional color conversion.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An image processing apparatus comprising:
first color conversion data in which a relationship between a color in a color space corresponding to an input image and a color corresponding thereto in a device-independent color space is recorded;
second color conversion data in which a relationship between a color material amount of an output equipment and a color corresponding thereto in the device-independent color space is recorded;
pure gray data in which a value of a black color amount corresponding to lightness is described;
achromatic color on-axis lattice point calculation means for calculating achromatic color on-axis lattice point data from the first color conversion data;
one-dimensional look-up table generation means for generating one-dimensional look-up table data from the achromatic color on-axis lattice point data calculated by the achromatic color on-axis lattice point calculation means;
three-dimensional look-up table generation means for generating first three-dimensional look-up table data from the first color conversion data, the second color conversion data, and the pure gray data; and
first color conversion means for converting the input image into the color material amount of the output device from the one-dimensional look-up table data generated by the one-dimensional look-up table generation means and the first three-dimensional look-up table data generated by the three-dimensional look-up table generation means.

2. The image processing apparatus according to claim 1, wherein the three-dimensional look-up table generation means includes three-dimensional table lattice point calculation means for calculating three-dimensional table lattice point data from the achromatic color on-axis lattice point data calculated by the achromatic color on-axis lattice point calculation means, second color conversion means for converting the three-dimensional table lattice point data calculated by the three-dimensional table lattice point calculation means into second three-dimensional look-up table data, and pure gray conversion means for generating the first three-dimensional look-up table data based on the pure gray data by using the second three-dimensional look-up table data converted by the second color conversion means.

3. The image processing apparatus according to claim 2, wherein the second color conversion means includes third conversion means for converting an RGB value of the three-dimensional table lattice point data into a CIELAB value based on the first color conversion table, gamut generation means for generating gamut data based on the second color conversion data, fourth color conversion means for converting the CIELAB value into a new CIELAB value based on the gamut data generated by the gamut generation means, inverse conversion table generation means for generating third three-dimensional look-up table data based on the second color conversion data 12, and fifth color conversion means for converting the new CIELAB value converted by the fourth color conversion means into a CMYK value based on the third three-dimensional look-up table data generated by the inverse conversion table generation means.

4. The image processing apparatus according to claim 3, wherein the fifth color conversion means outputs second three-dimensional look-up table data in which the new CIELAB value was converted into the CMYK value.

5. An image processing apparatus comprising:
first color conversion data in which a relationship between a color in a color space corresponding to an input image and a color corresponding thereto in a device-independent color space is recorded;
second color conversion data in which a relationship between a color material amount of an output equipment and a color corresponding thereto in the device-independent color space is recorded;
pure gray data in which a value of a black color amount corresponding to lightness is described;
an achromatic color on-axis lattice point calculation unit to calculate achromatic color on-axis lattice point data from the first color conversion data;
a one-dimensional look-up table generation unit to generate one-dimensional look-up table data from the achromatic color on-axis lattice point data calculated by the achromatic color on-axis lattice point calculation unit;
a three-dimensional look-up table generation unit to generate first three-dimensional look-up table data from the first color conversion data, the second color conversion data, and the pure gray data; and
a first color conversion unit to convert the input image into the color material amount of the output device from the one-dimensional look-up table data generated by the one-dimensional look-up table generation unit and the first three-dimensional look-up table data generated by the three-dimensional look-up table generation unit.

6. The image processing apparatus according to claim 5, wherein the three-dimensional look-up table generation unit includes a three-dimensional table lattice point calculation unit to calculate three-dimensional table lattice point data from the achromatic color on-axis lattice point data calculated by the achromatic color on-axis lattice point calculation unit, a second color conversion unit to convert the three-dimensional table lattice point data calculated by the three-dimensional table lattice point calculation unit into second three-dimensional look-up table data, and a pure gray conversion unit to generate the first three-dimensional look-up table data based on the pure gray data by using the second three-dimensional look-up table data converted by the second color conversion unit.

7. The image processing apparatus according to claim 6, wherein the second color conversion unit includes a third conversion unit to convert an RGB value of the three-dimensional table lattice point data into a CIELAB value based on the first color conversion table, a gamut generation unit to generate gamut data based on the second color conversion data, a fourth color conversion unit to convert the CIELAB value into a new CIELAB value based on the gamut data generated by the gamut generation unit, an inverse conversion table generation unit to generate third three-dimensional look-up table data based on the second color conversion data 12, and a fifth color conversion unit to convert the new CIELAB value converted by the fourth color conversion unit into a CMYK value based on the third three-dimensional look-up table data generated by the inverse conversion table generation unit.

8. The image processing apparatus according to claim 7, wherein the fifth color conversion unit outputs second three-dimensional look-up table data in which the new CIELAB value was converted into the CMYK value.

9. An image processing method for performing an image processing having first color conversion data in which a relationship between a color in a color space corresponding to an input image and a color corresponding thereto in a device-independent color space is recorded, second color conversion data in which a relationship between a color material amount of an output equipment and a color corresponding thereto in the device-independent space is recorded, and pure gray data in which a value of a black color amount corresponding to lightness is described, the method comprising:
calculating achromatic color on-axis lattice point data from the first color conversion data;
generating one-dimensional look-up table data from the calculated achromatic color on-axis lattice point data;
generating first three-dimensional look-up table data from the first color conversion data, the second color conversion data and the pure gray data; and
converting the input image into the color material amount of the output device from the generated one-dimensional look-up table data and the generated first three-dimensional look-up table data.

10. The image processing method according to claim 9, wherein three-dimensional table lattice point data is calculated from the calculated achromatic color on-axis lattice point data, the calculated three-dimensional table lattice point data is converted into second three-dimensional look-up table data, and the first three-dimensional look-up table data is generated based on the pure gray data by using the converted second three-dimensional look-up table data.

11. The image processing method according to claim 9, wherein an RGB value of the three-dimensional table lattice point data is converted into a CIELAB value based on the first color conversion table, gamut data is generated based on the second color conversion data, the CIELAB value is converted into a new CIELAB value based on the generated gamut data, third three-dimensional look-up table data is generated based on the second color conversion data, and the converted new CIELAB value is converted into a CMYK value based on the generated third three-dimensional look-up table data to output second three-dimensional look-up table data.
